(19) United States
(12) Patent Application Publication
(10) Pub. No.: US 2008/0096318 A1
(43) Pub. Date: Apr. 24, 2008

(54) METHOD OF CONNECTING CARRIER TAPES AND TCP MOUNTING APPARATUS USED THEREFOR

(75) Inventor: Tsukasa Hariu, Kanagawa (JP)

Correspondence Address: YOUNG & THOMPSON, 745 SOUTH 23RD STREET, 2ND FLOOR, ARLINGTON, VA, 22202, US

(73) Assignee: NEC LCD TECHNOLOGIES, LTD., KANAGAWA (JP)

(21) Appl. No.: 11/874,467

(22) Filed: Oct. 18, 2007

(30) Foreign Application Priority Data
Oct. 20, 2006 (JP) 2006-286877

(51) Int. Cl. H01L 21/58; B65H 21/00

(52) U.S. Cl. 438/110; 156/159; 156/502; 257/E21.505

(57) ABSTRACT

A method of connecting carrier tapes in the TCP mounting apparatus is provided, which makes it surer to form an interconnection between the end portion of a current carrier tape and the beginning portion of a new carrier tape, and which is easy to be carried out. The end portion of the current carrier tape is positioned and held by a movable first member and the beginning portion of the new carrier tape is positioned and held by a movable second member. The end portion is sandwiched between the first and second members and then, an unnecessary part of the end portion is cut off using the cutter on the first member. The remaining end portion and the beginning portion are overlapped and thereafter, they are interconnected in the overlapped section, and detached from the first and second members, respectively.

### BACKGROUND OF THE INVENTION

1. Field of the Invention

The present invention relates to a method of connecting carrier tapes. More particularly, the invention relates to a method of connecting the end portion of a currently used carrier tape to the beginning portion of a carrier tape to be used next in a Tape Carrier Package (TCP) mounting apparatus, a TCP mounting apparatus used for the method, and a method of fabricating a display device.

2. Description of the Related Art

TCP technology is a technology that the electrodes or bumps of unpackaged semiconductor chips (i.e. bare chips) are bonded in a lump to the inner leads of a tape-shaped Flexible Printed Circuit (PPC) (i.e., a carrier tape) on which circuit patterns are printed, thereby mounting many semiconductor chips on the carrier tape continuously. The FPC or carrier tape on which the chips have been mounted are then divided into pieces to include the chips one by one and thereafter, mounted or bonded to desired external devices, respectively.

The carrier tape comprises a flexible base material made of plastic such as polyimide, on which inner leads, outer leads, and wiring lines for interconnection between the inner leads and the outer leads are printed with cupper (Cu). Each of the semiconductor chips bonded to the inner leads in a lump is usually encapsulated by a sealing resin to avoid the effect of moisture. The package including many semiconductor chips that are joined together at predetermined intervals and encapsulated by the resin on the carrier tape in this way is termed the Tape Carrier Package (TCP) TCP technology may be termed Chip On Film (COP) technology because semiconductor chips are mounted on a flexible film having wiring lines.

The carrier tape has many chip or device windows (which are used for placement of the semiconductor chips) formed at a predetermined pitch. Each of the semiconductor chips is bonded in a lump to the inner leads formed at each of the windows. The opposite side of the windows to the bonding positions to the semiconductor chips is covered with a cover tape. The carrier tape on which the semiconductor chips have been bonded or mounted in this way is placed around a reel (i.e., a carrier tape reel) and then, stored or used in the same state.

Moreover, the carrier tape further has many feeding or sprocket holes formed along the arrangement of the chip windows at a predetermined pitch. These feeding or sprocket holes are used for movement and positioning of the carrier tape when the semiconductor chips are placed in the respective windows and bonded to the inner leads in a lump. These holes are also used for movement and positioning of the carrier tape when the chips placed on the carrier tape are mounted onto external devices while pulling out the carrier tape from the reel.

The TCP mounting apparatus is an apparatus for mounting or bonding the many semiconductor chips arranged on the carrier tape onto external devices respectively while pulling out the carrier tape from the reel, where a series of mounting operations are carried out automatically. When mounting each of the semiconductor chips onto an external device from the carrier tape, the carrier tape is divided by cutting at intervals of a predetermined length in such a way as to include the chips one by one. The chips on the pieces of the carrier tape thus divided (i.e., carrier tape pieces) are successively connected to external devices using the outer leads on the respective pieces.

The TCP mounting apparatus is practically used in the fabrication of the Liquid-Crystal Display (LCD) device, for example. Typically, the LCD device comprises a substrate on which switching elements such as Thin-Film Transistors (TFTs) are formed (which is termed the “TFT substrate”), an opposing substrate on which a color filter, a black matrix and so on are formed, and a liquid-crystal layer placed between the TFT substrate and the opposing substrate. The alignment direction of the liquid-crystal molecules in the liquid-crystal layer is changed by the electric field generated between the electrodes on the TFT substrate and that on the opposing substrate or between the electrodes on the TFT substrate, thereby controlling the transmittance of light in the respective pixels to display images. On the TFT substrate, various wiring lines, such as gate electrode lines (i.e., scanning lines), drain electrode lines (i.e. data lines), and common electrode lines, are formed to be lattice-shaped. These wiring lines are electrically connected to the semiconductor chip for an external driving circuit. The switching elements are driven by the semiconductor chip for an external driving circuit, thereby displaying images.

When the semiconductor chips for driving circuits arranged or mounted on the carrier taps are mounted on the TFT substrate or LCD panel, the carrier tape is divided by cutting into pieces (i.e., carrier tape pieces) each having a predetermined length while pulling out the carrier tape from the reel and peeling the cover tape off from the said tape. Thereafter, the outer leads (which are electrically connected to the semiconductor chip) formed on one side of each carrier tape piece thus obtained are bonded to the predetermined positions or electrodes of the TFT substrate with an Anisotropic Conductive Film (ACF). In this way, the mounting operations of the semiconductor chip are completed.

The outer leads formed on the other side of the carrier tape piece that has been bonded to the TFT substrate (these outer leads are also electrically connected to the semiconductor chip) are connected to a predetermined Printed Wiring Board (PWB) by soldering.

By the way, when the semiconductor chips for driving circuits arranged on the carrier tape are sequentially mounted on the TFT substrates in the fabrication of the LCD device using the TCP mounting apparatus, if all the semiconductor chips mounted on a carrier tape reel are bonded to the TFT substrates, it is necessary to replace the said reel with another carrier tape reel of the same type. At that time, to continue the TCP mounting operation, the end portion of the carrier tape in use (which may be termed the “current carrier tape”) is overlapped with the beginning portion of a next carrier tape (which may be termed a “new carrier tape”) and then, the two arms of staples are penetrated through the overlapped regions of these two tapes and bent at two positions, resulting in an interconnection between the current and new carrier tapes. The positioning step of the current and new carrier tapes in the interconnection operation is carried out by matching the feeding or sprocket holes in the end portion of the current carrier tape with those in the beginning portion of the new carrier tape. It is usual that this interconnection operation is manually conducted by an operator. After the interconnection is completed, the same mounting operation as conducted for the current carrier tape is continued for the new carrier tape thus loaded.

In addition, the chip windows and the cover tape are not placed in the beginning and end portions of each of the carrier tapes. Specifically, many chip windows and many sprocket holes are respectively arranged at predetermined pitches in the body of each carrier tape and at the same time, one side of the chip windows is covered with a cover tape. (There is a case where no cover tape is attached to the body.) Connecting tapes are respectively connected to the two ends of the body. No chip windows nor cover tape are provided in the connecting tapes.

In this specification, the part or portion of the carrier tape where the chip windows (and the cover tape, if necessary) are formed is termed the “body” of the carrier tape. At the same time, the parts or portions (e.g., the above-described connecting tapes) formed at each end of the body of the carrier tape, where no chip windows nor cover tape are formed, are respectively termed the “beginning portion” and the “end portion” of the carrier tape. Therefore, the current carrier tape has the beginning portion at its one end and the end portion at the other end. The new carrier tape has the same structure as this.

The prior-art techniques relating to the present invention are disclosed in the patent documents 1 and 2, for example.

The patent document 1 (the Japanese Non-Examined Patent Publication No. 3-224725 published in Oct. 3, 1991) discloses a method of connecting a plastic carrier tape that connects a ruptured plastic carrier tape formed during the fabrication of a plastic carrier tape. With this method, in the first step, the ruptured edge of a first strip of a plastic carrier tape and the ruptured edge of a second strip thereof are cut in such a way as to be narrower than the feed pitch at the time when contacting the ruptured edges of the first and second strips thus cut with each other and then, the first and second strips are aligned to have a gap between the edges thus cut. In the second step, a carrier tape having the same pitch as the first and second strips is cut in such a way as to include several pitches, thereby forming a third strip. In the third step, depressed holes or regions of the third strip are fitted into depressed holes or regions of the first and second strips and adhered together. (See claim 1 and FIGS. 1 to 4).

The patent document 2 (the Japanese Non-Examined Patent Publication No. 9-102219 published in Apr. 15, 1997) discloses a method of connecting conductive long tapes for carrier tapes, where each conductive long tape has a conductive layer on its one face or two conductive layers on its both faces. With this method, the ends of two conductive long tapes are overlapped with each other and then, the overlapped regions of the tapes are thermally compressed, thereby forming a connection section whose thickness is equal to the thickness of a single conductive long tape. Thereafter, a conductive layer is additionally formed on the connection section. (See claim 1 and FIGS. 1 to 3).

The method disclosed in the patent document 1 is a method for interconnecting the strips of a ruptured plastic carrier tape formed during the fabrication of the plastic carrier tape, in which the ruptured edges of the first and second strips are opposed and adhered to each other. Therefore, the method of the patent document 1 is different from the method of the present invention. This is because the method of the invention is a method of connecting the end portion of a currently used carrier tape to the beginning portion of a carrier tape to be used next in the TCP mounting apparatus, when the semiconductor chips arranged on the carrier tapes are repeatedly mounted on external devices such as the TFT substrates or the LCD panels.

Similar to the method of the patent document 1, the method disclosed in the patent document 2 is a method of connecting conductive long tapes for the carrier tape in the fabrication of the carrier tape itself. Therefore, because of the same reason as the patent document 1, the method of the patent document 2 is different from method of the present invention also.

With the above-described conventional carrier tape connecting method used in the fabrication of the LCD device, there is a possibility that defective interconnection of the carrier tapes occurs. For example, there is a possibility that one of the two arms of the staple is unable to penetrate through the both carrier tapes (i.e., the end portion of the current carrier tape and the beginning portion of the new carrier tape), and that the staple itself is not pressed out from its reception or storage section as designed. In this case, the interconnection between the carrier tapes (i.e., the end portion of the current carrier tape and the beginning portion of the new carrier tape) may be unstable. As a result, there arises a problem that each of the semiconductor chips on the new carrier tape cannot be divided by cutting at the desired positions before and after the said chip, thereby feeding the chip in the form of carrier tape piece to the desired TFT substrate or LCD panel. Alternately, there arises another problem that the new carrier tape cannot be even divided by cutting at the desired positions before and after each of the chips to thereby form carrier tape pieces.

These problems will cause an interruption of the TCP mounting operation of the semiconductor chips onto the TFT substrates or LCD panels (which should be originally carried out without any stop time) in the fabrication of the LCD devices. Such the interruption leads to not only reduction of the operating time of the TCP mounting apparatus but also compulsion with an operator to correct the defectively interconnection section of the carrier tapes, resulting in an increase in the fabrication cost of the LCD device.

Moreover, there is a possibility that these problems occur in the fabrication not only of the LCD device but also the fabrication of other types of the display devices excluding the LCD device, if it includes the step of mounting the semiconductor chips arranged on the carrier tape onto desired devices repeatedly.

### SUMMARY OF THE INVENTION

The present invention was created through the consideration about the above-described problems in the above-described conventional carrier tape connecting method.

An object of the present invention is to provide a method of connecting carrier tapes in a TCP mounting apparatus that makes it surer to form an interconnection between the end portion of a current carrier tape and the beginning portion of a new carrier tape, and that is easy to be carried out, a TCP mounting apparatus, and a method of fabricating a display device.

Another object of the present invention is to provide a method of connecting carrier tapes in a TCP mounting apparatus that makes it possible to stabilize the interconnection state between the end portion of a current carrier tape and the beginning portion of a new carrier tape to thereby avoid the problem caused by the instability of the said interconnection state, a TCP mounting apparatus, and a method of fabricating a display device.

The above objects together with others not specifically mentioned will become clear to those skilled in the art from the following description.

According to the first aspect of the invention, a method of connecting carrier tapes in a TCP mounting apparatus for connecting an end portion of a first carrier tape to a beginning portion of a second carrier tape is provided.

This method comprises the steps of:

providing a first movable member having cutting means, holding means, and positioning means, and a second movable member having holding means and positioning means;

positioning and holding the end portion of the first carrier tape by the first member using the positioning means and the holding means of the first member;

positioning and holding the beginning portion of the second carrier tape by the second member using the positioning means and the holding means of the second member;

cutting an unnecessary part of the end portion of the first carrier tape by using the cutting means of the first member;

moving the first member and/or the second member to form an overlapping region where the beginning portion of the second carrier tape and the remaining end portion of the first carrier tape are overlapped, after cutting the unnecessary part of the end portion;

adhering the beginning portion of the second carrier tape and the remaining end portion of the first carrier tape to each other in the overlapping region by bringing the first member and the second member close to each other; and

detaching respectively the second member and the first member from the beginning portion of the second carrier tape and the remaining end portion of the first carrier tape, after adhering the beginning portion and the remaining end portion to each other.

With the method of connecting carrier tapes according to the first aspect of the invention, as explained above, the first movable member having the cutting means, the holding means, and the positioning means, and the second movable member having the holding means and the positioning means are provided. Then, the end portion of the first carrier tape is positioned and held by the first member using the positioning means and the holding means thereof. The beginning portion of the second carrier tape is positioned and held by the second member using the positioning means and the holding means thereof. Therefore, positioning and moving of the first and second carrier tapes can be made unnecessary by controlling the positions and movements of the first and second members.

Subsequently, the unnecessary part of the end portion of the first carrier tape is cut off by using the cutting means of the first member. Since the unnecessary part of the end portion of the first carrier tape is cut off in this step, there is no danger that the unnecessary part gives bad effects to the mounting operation of the chip-shaped elements or components and the carrying operation of the second carrier tape after the interconnection between the end portion of the first carrier tape and the beginning portion of the second carrier tape is completed.

Furthermore, the first and/or second member is/are moved to form the overlapping region where the beginning portion of the second carrier tape and the end portion of the first carrier tape are overlapped. Thereafter, the beginning portion of the second carrier tape and the remaining end portion of the first carrier tape are adhered to each other in the overlapping region by bringing the first and second members close to each other. Since this adhering operation is extremely simple, the adhesion between the beginning portion of the second carrier tape and the end portion of the first carrier tape is carried out simply and surely.

Finally, the second member and the first member are respectively detached from the beginning portion of the second carrier tape and the remaining end portion of the first carrier tape thus adhered.

As described above, with the method of connecting carrier tapes according to the first aspect of the invention, the beginning portion of the second carrier tape and the remaining end portion of the first carrier tape are adhered to each other in the above-described manner and therefore, the interconnection between the remaining end portion of the first carrier tape (i.e., a current carrier tape) and the beginning portion of the second carrier tape (i.e., a new carrier tape) can be formed more surely.

Accordingly, the interconnection state between the end portion of the first carrier tape and the beginning portion of the second carrier tape is stabilized and as a result, the problem caused by the instability of the said interconnection state can be avoided.

In addition, because it is sufficient that the first and second movable members each having the above-described means or structures are provided and are operated in the above-described manner, the method according to the first aspect can be carried out easily.

In a preferred embodiment of the method according to the first aspect of the invention, staples are additionally applied to the overlapping region in the adhering step of the beginning portion of the second carrier tape and the remaining end portion of the first carrier tape. In this embodiment, there is an additional advantage that the interconnection strength of the beginning portion of the second carrier tape and the remaining end portion of the first carrier tape can be enhanced.

In another preferred embodiment of the method according to the first aspect of the invention, a double-sided adhesive tape is placed between the beginning portion of the second carrier tape and the remaining end portion of the first carrier tape in the overlapping region in the adhering step of the beginning portion of the second carrier tape and the remaining end portion of the first carrier tape. In this embodiment, an additional advantage that the adhering step can be easily carried out occurs.

In still another preferred embodiment of the method according to the first aspect of the invention, thermally compressing means is used to form a thermal connection section in the overlapping region in the adhering step of the beginning portion of the second carrier tape and the remaining end portion of the first carrier tape, wherein the beginning portion and the remaining end portion are thermally interconnected in the thermal connection section. In this embodiment, there is an additional advantage that the adhering step is simplified. This is because coating process of an adhesive and placement process of an adhesive tape are unnecessary for adhesion, and because the adhesion of the beginning portion and the remaining end portion is achieved by temporarily melting and curing the beginning portion and the remaining end portion by the thermally compressing means.

In a further preferred embodiment of the method according to the first aspect of the invention, in the step of cutting the unnecessary part of the end portion of the first carrier tape, the entire beginning portion of the second carrier tape held by the second member is located behind a cutting position. In this embodiment, there is an additional advantage that even if the edge of the cutting means of the first member penetrates through the end portion of the first carrier tape toward the second member in the cutting step, the beginning portion of the second carrier tape is not affected by the edge.

In a still further preferred embodiment of the method according to the first aspect of the invention, after the cutting step of the unnecessary part of the end portion of the first carrier tape is completed, the unnecessary part of the end portion of the first carrier tape is held by the first member. In this embodiment, there is an additional advantage that bad effects to be given to the mounting operation and moving operation of the second carrier tape due to the unnecessary part of the end portion of the first carrier tape can be avoided.

In a still further preferred embodiment of the method according to the first aspect of the invention, the cutting means of the first member comprises an edge movable toward the second means, and the second member comprises a hole for receiving the edge, wherein the edge of the cutting means is moved to enter the hole through the end portion of the first carrier tape in the cutting step of the unnecessary part of the end portion of the first carrier tape. In this embodiment, there is an additional advantage that the cutting operation is carried out well and the cutting means can be made simple. This is because the unnecessary part of the end portion of the first carrier tape can be cut off as desired by simply moving the edge toward the second member in the state where the end portion is sandwiched by the first member and the second member.

According to the second aspect of the invention, a TCP mounting apparatus is provided, which comprises a function of conducting the method according to the first aspect of the invention.

Specifically, the TCP mounting apparatus according to the second aspect of the invention comprises:

a first movable member having cutting means, holding means, and positioning means; and

a second movable member having holding means and positioning means;

wherein the end portion of the first carrier tape is positioned and held by the first member using the positioning means and the holding means of the first member;

the beginning portion of the second carrier tape is positioned and held by the second member using the positioning means and the holding means of the second member;

an unnecessary part of the end portion of the first carrier tape is cut by using the cutting means of the first member;

the first member and/or the second member is/are moved to form an overlapping region where the beginning portion of the second carrier tape and the remaining end portion of the first carrier tape are overlapped, after cutting the unnecessary part of the end portion;

the beginning portion of the second carrier tape and the remaining end portion of the first carrier tape are adhered to each other in the overlapping region by bringing the first member and the second member close to each other; and

the second member and the first member are detached respectively from the beginning portion of the second carrier tape and the remaining end portion of the first carrier tape, after adhering the beginning portion and the remaining end portion to each other.

With the TCP mounting apparatus according to the second aspect of the invention, the function of conducting the method according to the first aspect of the invention is incorporated and therefore, the method of connecting carrier tapes according to the first aspect is carried out easily.

According to the third aspect of the invention, a method of fabricating a display device is provided, wherein a first movable member having cutting means, holding means, and positioning means, and a second movable member having holding means and positioning means are provided, and semiconductor chips are arranged on a first carrier tape and a second carrier tape, respectively; and the method according to the first aspect of the invention is used.

Specifically, the method of fabricating a display device according to the third aspect of the invention comprises the steps of:

after all the semiconductor chips arranged on the first carrier tape are mounted on respective external devices;

positioning and holding an end portion of the first carrier tape by the first member using the positioning means and the holding means of the first member;

positioning and holding a beginning portion of the second carrier tape by the second member using the positioning means and the holding means of the second member;

cutting an unnecessary part of the end portion of the first carrier tape by using the cutting means of the first member;

moving the first member and/or the second member to form an overlapping region where the beginning portion of the second carrier tape and the remaining end portion of the first carrier tape are overlapped, after cutting the unnecessary part of the end portion;

adhering the beginning portion of the second carrier tape and the remaining and portion of the first carrier tape to each other in the overlapping region by bringing the first member and the second member close to each other;

detaching respectively the second member and the first member from the beginning portion of the second carrier tape and the remaining end portion of the first carrier tape, after adhering the beginning portion and the remaining end portion to each other; and

mounting the semiconductor chips arranged on the second carrier tape on respective external devices, successively.

With the method of fabricating a display device according to the third aspect of the invention, the method of connecting carrier tapes according to the first aspect of the invention is used after all the semiconductor chips arranged on the first carrier tape are mounted on respective external devices. Therefore, the problem caused by the instability of the said interconnection state between the end portion of the first carrier tape and the beginning portion of the second carrier tape is avoided. Accordingly, an increase in the fabrication cost of the display device due to the said problem can be prevented.

### BRIEF DESCRIPTION OF THE DRAWINGS

In order that the present invention may be readily carried into effect, it will now be described with reference to the accompanying drawings.

FIG. 1 is a conceptual diagram showing the mechanism (the structure of an apparatus) to be used in a method of connecting carrier tapes in a TCP mounting apparatus according to a first embodiment of the invention.

FIGS. 2A to 2C are cross-sectional views showing the process steps of the method of connecting carrier tapes according to the first embodiment of the invention, respectively.

FIGS. 3A to 3C are cross-sectional views showing the process steps of the method of connecting carrier tapes according to the first embodiment of the invention, respectively, which are subsequent to the step of FIG. 2C.

FIG. 4 is a conceptual diagram showing the mechanism (the structure of an apparatus) to be used in a method of connecting carrier tapes in a TCP mounting apparatus according to a second embodiment of the invention.

FIGS. 5A to 5C are cross-sectional views showing the process steps of the method of connecting carrier tapes according to the second embodiment of the invention, respectively.

FIGS. 6A to 6C are cross-sectional views showing the process steps of the method of connecting carrier tapes according to the second embodiment of the invention, respectively, which are subsequent to the step of FIG. 5C.

FIG. 7 is a cross-sectional view showing the process step of the method of connecting carrier tapes according to the second embodiment of the inventions which is subsequent to the step of FIG. 6C.

FIG. 8 is a schematic partial plan view showing the structure of the carrier tape (i.e., the current carrier tape) currently used in the TCP mounting apparatus.

FIG. 9 is a schematic partial plan view showing the structure of the carrier tape (i.e., the new carrier tape) to be used next in the TCP mounting apparatus.

FIG. 10A is a schematic enlarged partial plan view showing the structure of the interconnection section between the end portion of the current carrier tape and the beginning portion of the new carrier tape, which are interconnected by the method of connecting carrier tapes according to the first embodiment of the invention.

FIG. 10B is a schematic enlarged partial cross-sectional view along the line XB-XB in FIG. 10A.

FIG. 11A is a schematic enlarged partial plan view showing the structure of the interconnection section between the end portion of the current carrier tape and the beginning portion of the new carrier tape, which are interconnected by the method of connecting carrier tapes according to the second embodiment of the invention.

FIG. 11B is a schematic enlarged partial cross-sectional view along the line XIB-XIB in FIG. 11A.

FIG. 12A is a schematic enlarged partial plan view showing the structure of the interconnection section between the end portion of the current carrier tape and the beginning portion of the new carrier tape, which are interconnected by a method of connecting carrier tapes according to a third embodiment of the invention.

FIG. 12B is a schematic enlarged partial cross-sectional view along the line XIIB-XIIB in FIG. 12A.

FIG. 13 is a conceptual block diagram showing the structure of a TCP mounting apparatus used in the method of connecting carrier tapes according to the first embodiment of the invention.

FIG. 14 is a schematic diagram showing the structure of the TCP feeder of the TCP mounting apparatus shown in FIG. 13.

### DETAILED DESCRIPTION OF THE PREFERRED EMBODIMENTS

Preferred embodiments of the present invention will be described in detail below while referring to the drawings attached.

### First Embodiment

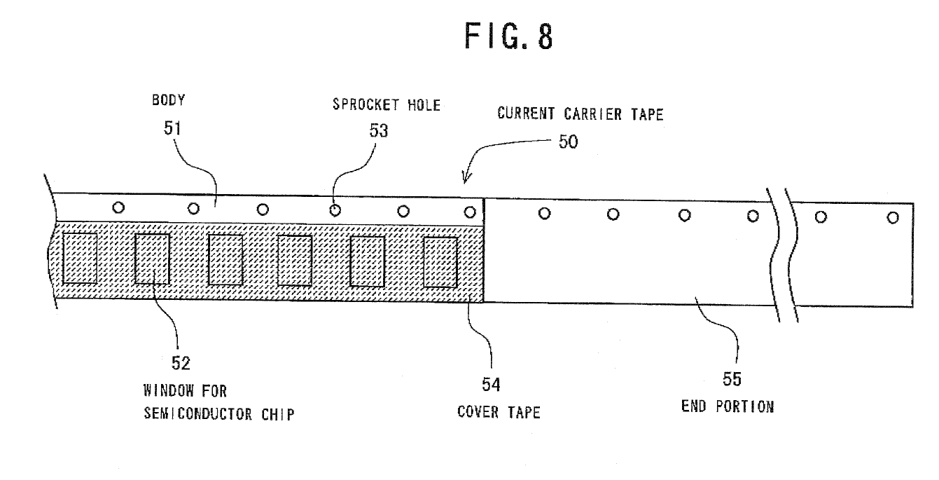

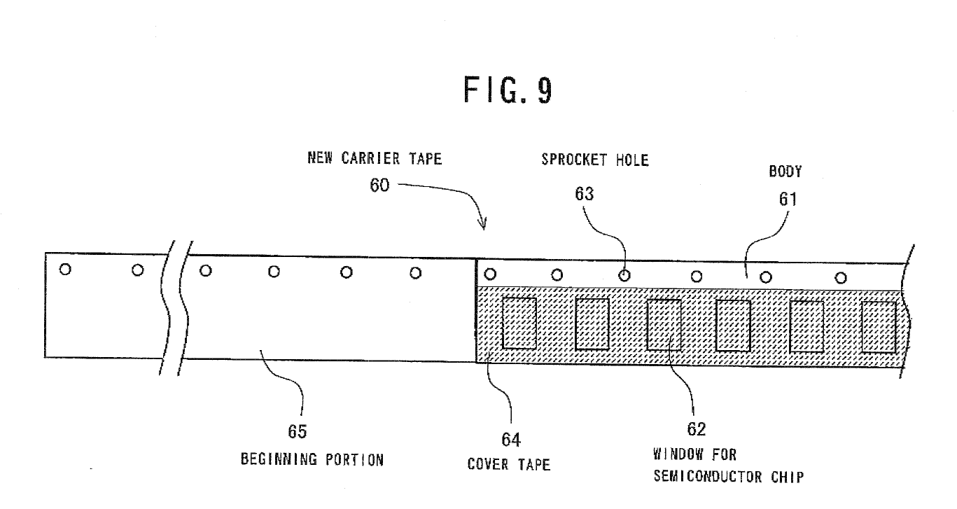

FIGS. 8 and 9 show the structure of a carrier tape (i.e., a current carrier tape) 50 currently used in a TCP mounting apparatus and a carrier tape (i.e., a new carrier tape) 60 to be used next therein, respectively.

The current carrier tape 50 shown in FIG. 8 which has the same structure as that of the known carrier tape of this type, comprises a body 51, an end portion 55 formed at one end of the body 51, and a beginning portion (not shown) formed at the other end of the body 51. The tail end of the end portion 55 is fixed to the carrier tape reel (not shown).

A plurality of rectangular windows 52 for placement of semiconductor chips (i.e., chip or device windows) is formed on the body 51. These windows 52 are aligned at a predetermined pitch along the longitudinal direction of the current carrier tape 50. As known well, inner leads (not shown) are formed to project into each of the windows 52. A semiconductor chip (not shown) is placed in the window 52 and bonded to the inner leads in a lump with the electrodes (bumps) of the chip.

Feed or sprocket holes 53 are formed in one of the longitudinal sides of the body 51. The holes 53 are aligned along the longitudinal direction of the current carrier tape 50 at a predetermined pitch. The holes 53 are used for feeding the tape 50 regularly and for positioning the tape 50 correctly.

A cover tape 54 is attached to one of the surfaces of the body 51 to cover all the chip windows 52. The tape 54 does not cover the sprocket holes 53.

The end portion 55, which is transparent and tape-shaped, is joined to one end of the body 51. Sprocket holes 53, which are the same as those in the body 51, are formed in one of the longitudinal sides of the end portion 55. However, chip windows 52 are not formed in the end portion 55. A cover tape 54 is not attached to the end portion 55 as well.

Although not shown, the beginning portion of the current carrier tape 50 has the same structure as that of the end portion 55.

The new carrier tape 60 shown in FIG. 9, which has the same structure as that of the current carrier tape 50, comprises a body 61, a beginning portion 65 formed at one end of the body 61, and an end portion (not shown) formed at the other end of the body 61. The tail end of the end portion of the tape 60 is fixed to the carrier tape reel (not shown).

A plurality of rectangular windows 62 for placement of semiconductor chips (i.e., chip or device windows) is formed on the body 61. These windows 62 are aligned at a predetermined pitch along the longitudinal direction of the new carrier tape 60. Inner leads (not shown) are formed to project into each of the windows 62. A semiconductor chip (not shown) is placed in the window 62 and bonded to the inner leads in a lump with the electrodes (bumps) of the chip.

Feed or sprocket holes 63 are formed in one of the longitudinal sides of the body 61. The holes 63 are aligned along the longitudinal direction of the new carrier tape 60 at a predetermined pitch. The holes 63 are used for feeding the tape 60 regularly and for positioning the tape 60 correctly.

A cover tape 64 is attached to one of the surfaces of the body 61 to cover all the chip windows 62. The tape 64 does not cover the sprocket holes 63.

The beginning portion 65, which is transparent and tape-shaped, is joined to one end of the body 61. Sprocket holes 63, which are the same as those in the body 61, are formed in one of the longitudinal sides of the beginning portion 65. However, chip windows 62 are not formed in the beginning portion 65. A cover tape 64 is not attached to the beginning portion 65 as well.

Although not shown, the end portion of the new carrier tape 60 has the same structure as that of the beginning portion 65.

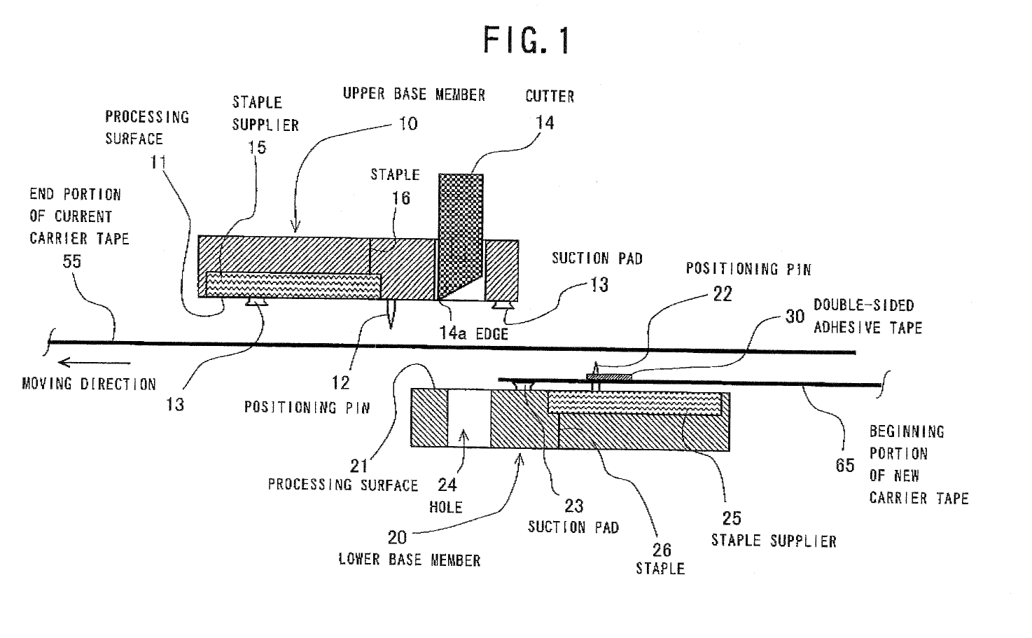

FIG. 1 is a conceptual diagram showing the mechanism (the structure of an apparatus) to be used in the method of connecting carrier tapes in a TCP mounting apparatus according to the first embodiment.

This method is carried out in a known TCP mounting apparatus excluding upper and lower base members 10 and 20 and therefore, it is preferred that the method is built in the said apparatus. This is because this method can be easily carried out. However, needless to say, this method may be carried out in a separate machine or apparatus.

Basically, the structure and functions of the TCP mounting apparatus are the same as those explained in BACKGROUND OF THE INVENTION. Specifically, the TCP mounting apparatus is an apparatus for mounting continuously many semiconductor chips arranged on a carrier tape onto external devices while pulling out the carrier tape from the reel, where a series of mounting operations are automatically carried out. When mounting the respective semiconductor chips onto the external devices, the carrier tape is divided by cutting at intervals of a predetermined length in such a way as to include the chips one by one. The chips on the pieces of the carrier tape thus divided (i.e., carrier tape pieces) are connected to the external devices using the outer leads on the pieces.

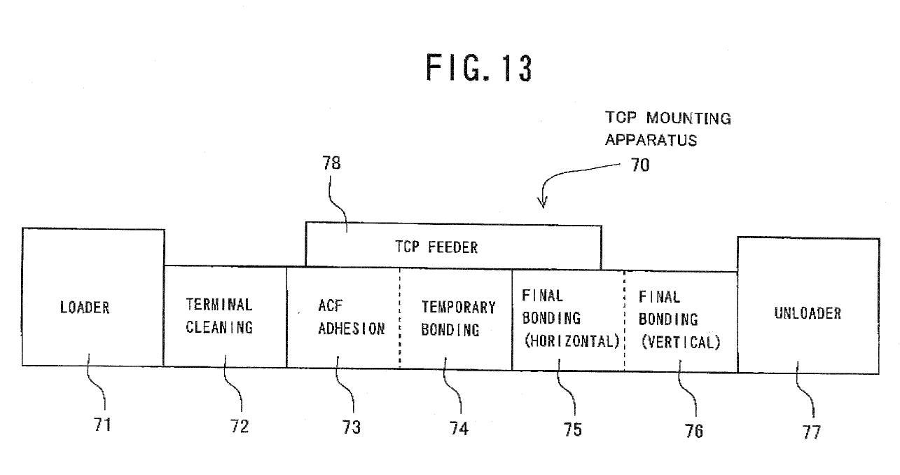

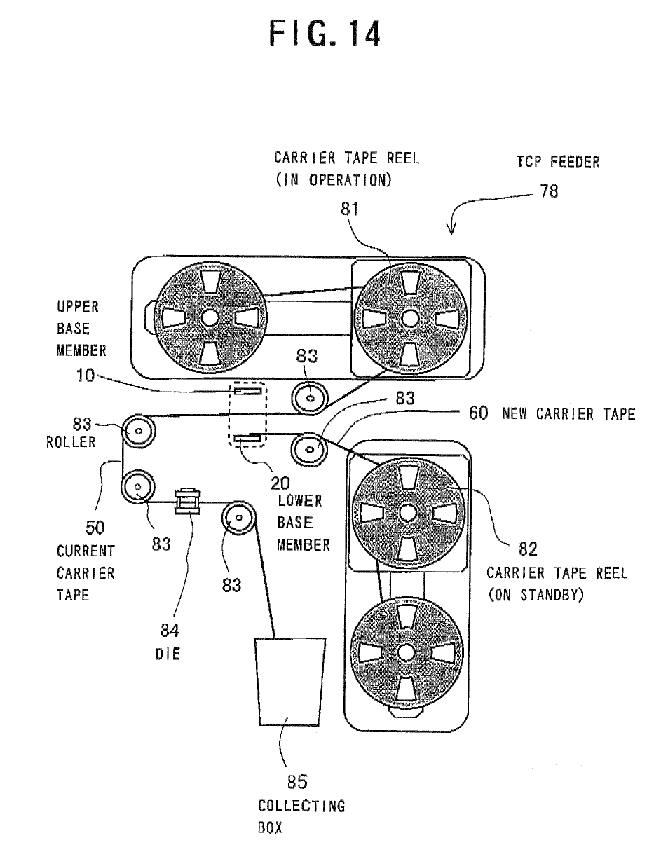

An example of the detailed structure of the TCP mounting apparatus will be explained later with reference to FIGS. 13 and 14.

With this method of connecting carrier tapes, an upper base member 10 and a lower base member 20 are used. The upper base member 10 and the lower base member 20 of this embodiment correspond to the first movable member and the second movable member in the claims, respectively. As explained in detail below, the upper base member 10 comprises cutting means, holding means, and positioning means for a carrier tape, and the lower base member 20 comprises holding means and positioning means for a carrier tape.

In the mounting operation, the current carrier tape 50 (and the new carrier tape 60) is (are) moved along the moving direction shown by the arrow in FIG. 1. Here, the moving direction (to the left in FIG. 1) of the current carrier tape 50 (and the new carrier tape 60) is termed “forward” and the opposite direction is termed “backward” in the following explanation.

The upper base member 10, which is located above the moving path of the current carrier tape 50, is movable in the upward and downward directions. The member 10 comprises a cutter 14 and a staple supplier 15. The cutter 14, which is movable upward and downward has an edge 14a at its lower end. When the cutter 14 is lowered, the edge 14a is protruded from the processing surface 11 formed on the lower surface of the member 10. Therefore, the end portion 55 of the current carrier tape 50 placed at the corresponding position to the edge 14a can be cut.

The staple supplier 15 pushes out an approximately U-shaped staple 16 downward from the processing surface 11 in each operation. The two arms of the staple 16 thus pushed out can penetrate through the end portion of the current carrier tape 50 and the beginning portion of the new carrier tape 60 which are held in the overlapped state at the corresponding position to the staple 16. The bending of the arms of the staple 16 thus pushed out is carried out by using the processing surface 21 of the lower base member 20 opposed to the upper base member 10.

A positioning pin 12 and two suction pads 13 are formed on the processing surface 11 of the upper base member 10. The positioning pin 12, which will be inserted into an appropriate one of the sprocket holes 53 of the current carrier tape 50 and engaged therewith, is used to position the current carrier tape 50 at a desired location and hold it at the same location.

The suction pads 13, which may be sucked onto the end portion 55 of the current carrier tape 50, are used to hold the current carrier tape 50 in the state where the tape 50 is positioned by the positioning pin 12. The pads 13 are in the form of sucker made of a flexible material such as rubber. The pads 13 are designed in such a way that a negative pressure is generated in the inside of the pads 13 by pressing them against the end portion 55, thereby holding the end portion 55 on the member 10. One of the pads 13 is located ahead of the cutter 14 and the positioning pin 12. The other of the pads 13 is located behind the cutter 14, in other words, at the rear end of the processing surface 11. This is to make it possible to hold both of the part of the end portion 55 ahead of the said cutting position and the part behind the same by the upper base member 10, even after the end portion 55 of the current carrier tape 50 has been cut.

The lower base member 20, which is located below the moving path of the current carrier tape 50, is movable in the forward and backward direction (i.e., the directions along the moving direction of the tape 50) and in the upward and downward directions. The member 20 comprises a penetrating hole 24 into which the edge 14a of the cutter 14 on the upper base member 10 may be inserted, and a staple supplier 25.

The staple supplier 25 pushes out an approximately U-shaped staple 26 upward from the processing surface 21. The two arms of the staple 26 thus pushed out can penetrate through the beginning portion of the new carrier tape 60 and the end portion of the current carrier tape 50 which are held in the overlapped state at the corresponding position to the staple 26. The bending of the arms thus pushed out is carried out by using the processing surface 11 of the upper base member 10 opposed to the lower base member 20.

A positioning pin 22 and a suction pad 23 are formed on the processing surface 21 formed at the upper end of the lower base member 20. The positioning pin 22, which may be inserted into an appropriate one of the sprocket holes 63 of the new carrier tape 60 and engaged therewith, is used to position the new carrier tape 60 at a desired location and hold it at the same location.

The suction pad 23, which may be sucked onto the beginning portion 65 of the new carrier tape 60, is used to hold the new carrier tape 60 in the state where the tape 60 is positioned by the positioning pin 22. The pad 23 is located between the hole 24 and the staple supplier 25. The structure of the pad 23 is the same as the pads 13 on the upper base member 10.

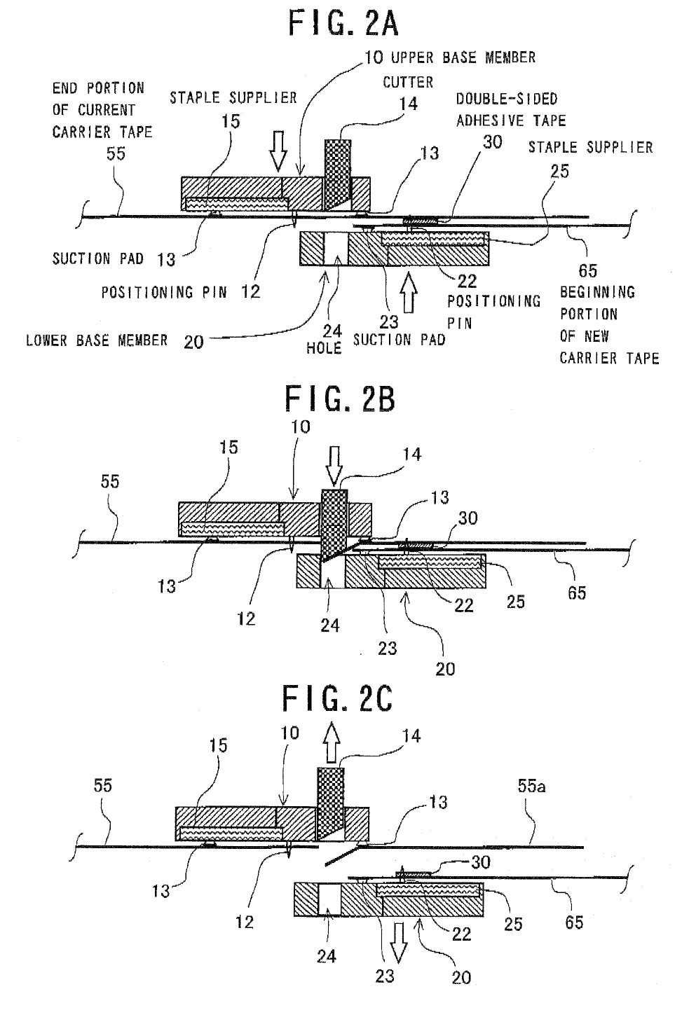

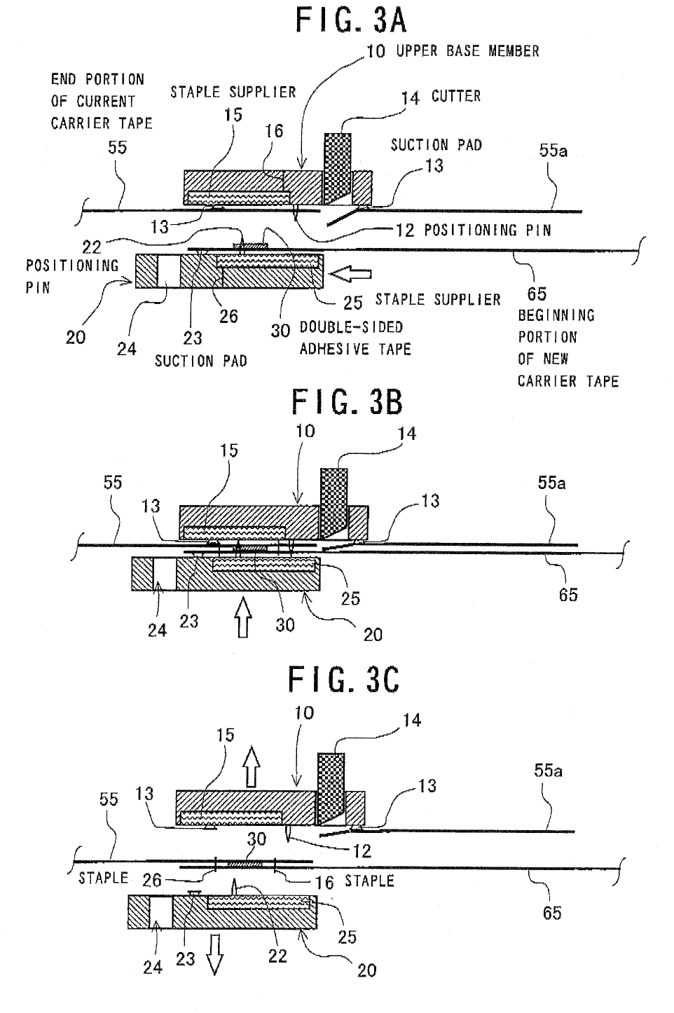

Next, the method of connecting the carrier tapes according to the first embodiment of the invention will be explained below with reference to FIG. 1, FIGS. 2A to 2C, and FIGS. 3A to 3C.

First, as shown in FIG. 1, in the standby state of the lower base member 20 where the member 20 is apart from the moving path of the current carrier tape 50 downward, the beginning portion 65 of the new carrier tape 60 is placed and held on the processing surface 21 of the lower base member 20. At this time, the positioning pin 22 of the member 20 is inserted into an appropriate one of the sprocket holes 63 of the beginning portion 65 and engaged therewith, thereby conducting the positioning operation of the new carrier tape 60. Moreover, in the vicinity of the top end of the beginning portion 65, the suction pad 23 is sucked onto the lower face (back surface) of the portion 65, thereby holding the new carrier tape 60 in the positioned state. The beginning portion 65 thus positioned and held on the member 20 is located behind the hole 24 and is not overlapped with the same. This is to avoid the cutting of the beginning portion 65 of the tape 60 when the edge 14a of the cutter 14 on the upper base member 10 is lowered and inserted into the hole 24.

One side (i.e., the lower side) of a double-sided adhesive tape 30 is attached to the beginning portion 65 of the new carrier tape 60 thus positioned and held on the lower base member 20. Here, the tape 30 is located at approximately the middle of the portion 65 widthwise near the positioning pin 22.

When the beginning portion 65 of the new carrier tape 60 is placed on the lower base member 20 in the above-described manner, the upper base member 10 is kept in its standby position, as shown in FIG. 1. In this standby state, the upper base member 10 is apart from the moving path of the current carrier tape 50 upward and is slightly shifted forward with respect to the lower base member 20.

Next, as shown in FIG. 2A, the upper base member 10 is lowered to the vicinity of the moving path of the current carrier tape 50 and then, the end portion 55 of the current carrier tape 50 is held on the processing surface 11 of the member 10 using the positioning pin 12 and the suction pads 13. At this time, the positioning pin 12 of the member 10 is inserted into an appropriate one of the sprocket holes 53 of the end portion 55 and engaged therewith, thereby conducting the positioning operation of the current carrier tape 50. Moreover, at two appropriate positions in the end portion 55, the suction pads 13 are sucked onto the upper face of the end portion 55, thereby holding the current carrier tape 50 in the positioned state. The end portion 55 thus positioned and held is extended forward and backward with respect to the upper base member 10.

The position at which the end portion 55 of the current carrier tape 50 is held by the upper base member 10 is optionally determined; however, it is preferred that this position is set to be near the body 51 of the current carrier tape 50. This is because it is preferred that the beginning portion 65 of the new carrier tape 60 is connected to the end portion 55 of the current carrier tape 50 at an appropriate position as close to the body 51 of the tape 50 as possible, from the viewpoint of stability after the interconnection is completed.

Subsequently, as shown in FIG. 2A, the lower base member 20 is raised from its standby position to the vicinity of the moving path of the current carrier tape 50 and then, stopped at a predetermined position that is matched with the upper base member 10. In this position, the cutter 14 of the upper base member 10 and the hole 24 of the lower base member 20 are superposed to each other. At this time, in order that the double-sided adhesive tape 30 placed on the beginning portion 60 of the new carrier tape 60, which has been held by the lower base member 20, may not contact the end portion 55 of the current carrier tape 50, a gap is preferably provided between the adhesive tape 30 and the end portion 55.

Next, the cutter 14 on the upper base member 10 is operated to lower the edge 14a. Since the end portion 55 of the current carrier tape 50 is held on the member 10 by the two suction pads 13, the end portion 55 is cut as desired at an opposing position to the edge 14a and thereafter, the edge 14a goes into the hole 24 through the cutting position of the tape 50. In this way, the end portion 55 of the current carrier tape 50 is cut off over its entire width. At this time, since the beginning portion 65 of the new carrier tape 60 does not exist at the position right above the hole 24 of the lower base member 20, no effect is given to the beginning portion 65. The cut point of the end portion 55 of the current carrier tape 50 is automatically determined at the time when the end portion 55 is positioned and held on the upper base member 10.

The reason why the end portion 55 of the current carrier tape 50 is cut at this stage is as follows.

First, the tail end of the end portion 55 is fixed to the carrier tape reel on which the current carrier tape 50 is wounded. Therefore, the tail end needs to be separated from the said reel for further movement of the tape 50. Second, it is preferred that the end portion 55 is separated as early as possible to shorten the tact time.

After the out of the end portion 55 of the current carrier tape 50 is completed in this way, the cutter 14 is raised and returned to its original position while keeping the upper base member 10 at the same position. On the other hand, the lower base member 20 is lowered to be apart from the moving path of the current carrier tape 50, as shown in FIG. 2C. At this time, the separated or unnecessary part 55a of the end portion 55 is being held by the rear suction pad 13 and thus, the part 55a does not fall. This means that the cut of the end portion 55 will not cause any problem in the mounting and moving operations. The state of the beginning portion 65 of the new carrier tape 60 held on the lower base member 20 and that of the adhesive tape 30 attached onto the portion 65 are the same as those shown in FIG. 1.

Next, as shown in FIG. 3A, the lower base member 20 is moved forward over a predetermined distance along the moving path of the current carrier tape 50 while keeping the member 20 apart from the said moving path. This is to overlap the beginning end 65 of the new carrier tape 60 with the remaining end portion 55 of the current carrier tape 50. Since the overlapping position and the overlapping length of the beginning and end portions 65 and 60 are dependent upon the movement distance of the lower base member 20 in this step, the said movement distance may be optionally determined according to the necessity. However, the said movement distance needs to be determined in such a way that the separated or unnecessary part 55a of the end portion 50 (which is kept being held by the upper base member 10) does not overlap with the lower base member 20.

Following this, the lower base member 20 is raised and then, the remaining end portion 55 of the current carrier tape 50 after cutting and the beginning portion 65 of the new carrier tape 60 are overlapped and contacted each other. In this state, the end portion 55 and the beginning portion 65 are sandwiched by the processing surface 11 of the upper base member 10 and the processing surface 21 of the lower base member 20, as shown in FIG. 3B. Moreover, the double-sided adhesive tape 30 placed on the beginning portion 65 of the new carrier tape 60 is pressed against the opposing area of the remaining end portion 55 of the current carrier tape 50.

Next, while keeping the state where the remaining end portion 55 of the current carrier tape 50 and the beginning portion 65 of the new carrier tape 60 are sandwiched by the processing surfaces 11 and 21 shown in FIG. 3B, the staple supplier 15 on the upper base member 10 and the staple supplier 25 on the lower base member 20 are activated, thereby pushing out a staple 16 downward from the upper base member 10 and a staple 26 upward from the lower base member 20. The two arms of the staple 16 thus pushed out downward from the upper base member 10 penetrate through the remaining end portion 55 and the beginning portion 65 at the two positions slightly behind the adhesive tape 30, reaching the opposing points of the processing surface 21 of the lower base member 20. Then, the arms of the staple 16 are bent by the processing surface 21 toward predetermined directions at those points. Similarly, the two arms of the staple 26 thus pushed out upward from the lower base member 20 penetrate through the beginning portion 65 and the end portion 55 at the two positions slightly ahead of the adhesive tape 30, reaching the opposing points of the processing surface 11 of the upper base member 10. Then, the arms of the staple 26 are bent by the processing surface 11 toward predetermined directions at those points.

In this way, as shown in FIG. 3B, the remaining end portion 55 of the current carrier tape 50 and the beginning portion 65 of the new carrier tape 60 are interconnected by the two staples 16 and 26 at the predetermined positions ahead of and behind the tape 30.

In the above staple pushing-out and bending step, pressing forces are applied to the adhesive tape 30 placed on the beginning portion 65 of the now carrier tape 60 between the staples 16 and 26. Therefore, the tape 30 is automatically pressed against the remaining end portion 55 and the beginning portion 65, resulting in an interconnection of the remaining end portion 55 and the beginning portion 65 by the tape 30. In this way, the interconnection of the end portion 55 and the beginning portion 65 is accomplished by not only the staples 16 and 26 but also the adhesive tale 30.

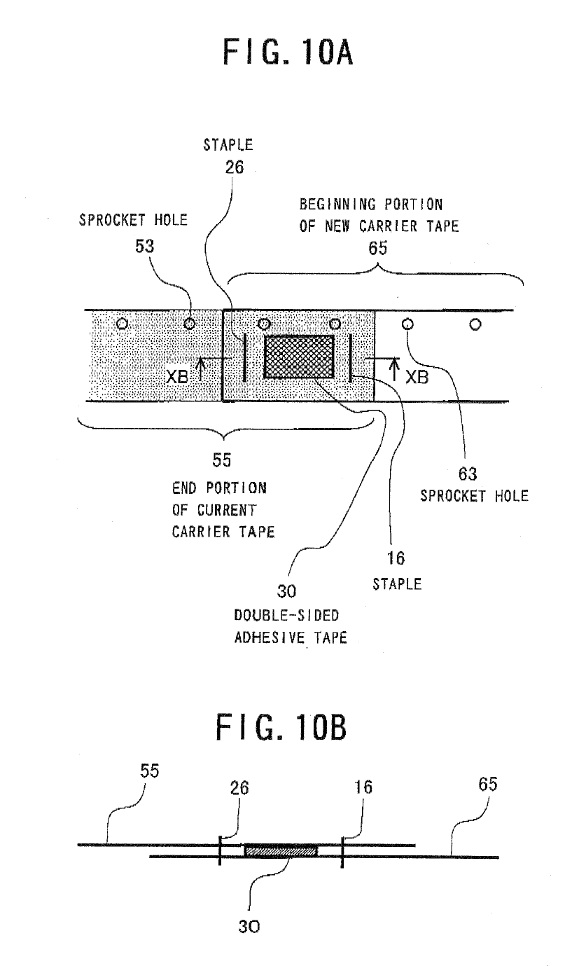

The schematic structure of the interconnection section of the remaining end portion 55 of the current carrier tape 50 and the beginning portion 65 of the new carrier tape 60 is shown in FIGS. 10A and 10B. FIG. 10A is an enlarged schematic plan view of the interconnection section and FIG. 10B is a partial cross-sectional view along the line XB-XB in FIG. 10A.

As shown in FIGS. 10A and 10B, the arms of the staple 16 pushed out downward from the upper base member 10 penetrate through the end portion 55 of the current carrier tape 30 and the beginning portion 65 of the new carrier tape 60 at the two positions slightly behind the adhesive tape 30. Thereafter, the both ends of the staple 16 thus penetrating are bent inward by the processing surface 21 in such a way as to be opposed to each other. On the other hand, the two arms of the staple 26 pushed out upward from the lower base member 20 penetrates through the beginning portion 65 of the new carrier tape 60 and the end portion 55 of the current carrier tape 50 at the positions slightly ahead of the adhesive tape 30. Thereafter, the both ends of the staple 26 thus penetrating are bent inward by the processing surface 11 in such a way as to be opposed to each other. Moreover, the top and bottom faces of the double-sided adhesive tape 30 are adhered to the remaining end portion 55 and the beginning portion 65, respectively. Accordingly, the interconnection strength of the remaining end portion 55 and the beginning portion 65 is surely enhanced compared with the conventional method that uses staples only.

In addition, because unintentional positional deviation or shift is unlikely to occur between the remaining end portion 55 and the beginning portion 65, the interconnection state of the end portion 55 and the beginning portion 65 is stabilized.

When the staple pushing-out and bending step is completed, the interconnection operation of the remaining end portion 55 of the current carrier tape 50 and the beginning portion 65 of the new carrier tape 60 is completed as well. Hence, as shown in FIG. 3C, the upper base member 10 is raised and the lower base member 20 is lowered from the moving path of the current carrier tape 50, thereby separating respectively the members 10 and 20 from the end portion 55 and the beginning portion 65 which have been interconnected. Thus, the method of connecting the carrier tapes according to the first embodiment of the invention is completed.

Additionally, the separated or unnecessary part 55a of the end portion 55 of the current carrier tape 50 held by the upper base member 10 may be detached from the member 10 in the state of FIG. 3C.

With the method of connecting carrier tapes according to the first embodiment of the invention, as explained above, the movable upper base member 10 (a first movable member) having the cutter 14 (cutting means), the suction pads 13 (holding means), and the positioning pin 12 (positioning means), and the movable lower base member 20 (a second movable member) having the suction pad 23 (holding means) and the positioning pin 22 (positioning means) are provided in the TCP mounting apparatus.

Then, first, the end portion 55 of the current carrier tape 50 (a first carrier tape) is positioned and held by the upper base member 10, and the beginning portion 65 of the new carrier tape 60 (a second carrier tape) is positioned and held by the lower base member 20. Subsequently, the end portion 55 of the current carrier tape 50 is sandwiched by the upper and lower base members 10 and 20 and then, the unnecessary part 55a of the end portion 55 is cut off by the cutter 14 of the upper base member 10. Furthermore, after the beginning portion 65 of the new carrier tape 60 and the remaining end portion 55 of the current carrier tape 50 are overlapped, the beginning portion 65 and the remaining end portion 55 are adhered to each other using the staples 16 and 26 and the double-sided adhesive tape 30. Therefore, the interconnection between the remaining end portion 55 of the current carrier tape 50 and the beginning portion 65 of the new carrier tape 60 are formed more surely.

Accordingly, the interconnection state between the end portion 55 of the current carrier tape 50 and the beginning portion 65 of the new carrier tape 60 is stabilized and as a result, the problems caused by the instability of the said interconnection state (e.g., the chip-shaped elements or parts in the form of TCP cannot be fed, or the FPC on which the chip-shaped elements or parts have been mounted cannot be divided) can be avoided.

In addition, it is sufficient that the upper base member 10 having the cutter 14, the suction pads 13, and the positioning pin 12, and the lower base member 20 having the suction pad 23 and the positioning pin 22 are provided and operated in the above-described manner. Therefore, the method of the first embodiment can be carried out easily.

Furthermore, it is sufficient for the operator that the end portion 55 of the current currier tape 50 is positioned and held by the upper base member 10, and the beginning portion 65 of the new currier tape 60 is positioned and held by the lower base member 20, and thereafter, the double-sided adhesive tape 30 is adhered onto the beginning portion 65. The subsequent operations are carried out automatically. Therefore, the burden for the operator does not increase.

In addition, the staples 16 and 26 are respectively supplied from the upper and lower base members 10 and 20 in the above-described first embodiment. However, the staple may be supplied one of the members 10 and 20 only. If so, the staple supplier 15 or 25 is unnecessary for the base member 10 or 20 that does not supply staples. Therefore, there is an additional advantage that the structure of the base member 10 or 20 is simplified.

If sufficient interconnection strength and stability are obtainable with the adhesive tape 30 alone, the staples 16 and 26 may be omitted. (Refer to the third embodiment explained later about this point.) Instead of the tape 30, a pressure-sensitive adhesive may be applied to the area of the beginning portion 65 where the tape 30 is to be adhered.

The above-described method of connecting carrier tapes in the TCP mounting apparatus according to the first embodiment may be applied to the fabrication of the LCD device, if driving semiconductor chips for LCD devices are used as the semiconductor chips arranged (mounted) on the current and new carrier tapes 50 and 60. In this case, in the TCP mounting apparatus, each of the driving semiconductor chips on the current carrier tape 50 is divided by cutting at the positions before and after the said chip into carrier tape pieces with a predetermined length while the current carrier tape 50 is sequentially pulled out from the carrier tape reel and the cover tape 54 is peeled off from the tape 50. Thereafter, the outer leads (which have been electrically connected to the driving semiconductor chip) formed at one side of each carrier tape piece thus obtained are bonded to the predetermined position of the TFT substrate or LCD panel using an ACF. In this way, the mounting operation for the driving semiconductor chips is completed.

As explained above, if the method of the first embodiment is applied to the fabrication of the LCD device, the problem caused by the instability of the interconnection state of the end portion 55 of the current carrier tape 50 and the beginning portion 65 of the new carrier tape 60 is avoided. As a result, an increase in the fabrication cost of the LCD device due to the said problem can be prevented.

Additionally, needless to say, the method of the first embodiment may be applied to other types of the display devices than the LCD device if it is fabricated using a TCP mounting apparatus.

FIG. 13 shows the structure of the TCP mounting apparatus used in the method of connecting carrier tapes according to the first embodiment of the invention.

The TCP mounting apparatus 70 shown in FIG. 13A comprises a loader 71, a terminal cleaning section 72, an ACF adhesion section 73, a temporary bonding section 74, a final bonding section 75 for the horizontal direction, a final bonding section 76 for the vertical direction, an unloader 77, and a TCP feeder 78.

In the loader 71, LCD panels stored in a cassette are picked up and fed to the next terminal cleaning step, successively.

In the terminal cleaning section 72, the terminals or electrodes on the respective LCD panels are cleaned with a wiping tape on which ethanol has been dropped and blowing air, successively.

In the ACF adhesion section 73, an ACF (anisotropic conductive film) is pulled out and cut off to form ACF pieces of a predetermined length and thereafter, the ACF pieces thus formed are attached onto the respective LCD panels in a lump under pressure, successively.

In the TCP feeder 78, TCPs are supplied in the form of a TCP carrier tape. The TCP carrier tape is pulled out from the carrier tape reel and punched out with a die to form separated TCPs and thereafter, the TCPs thus separated are sent to the temporary bonding section 75.

In the temporary bonding section 74, the separated TCPs which have been fed from the TCP feeder 78 are positioned at a predetermined position on the respective LCD panels by automatic positional recognition and thereafter, they are bonded on the panels temporarily with a thermal head (i.e., outer lead bonding), successively. In this operation, high-precision positioning of the TCPs at a predetermined location is automatically accomplished by visual recognition.

In the final bonding section 75 for the horizontal direction and the final bonding section 76 for the vertical direction, the TCPs temporarily bonded onto the respective LCD panels are finally bonded with a thermal head, successively. The final bonding step for the horizontal terminals and that for the vertical terminals are carried out separately in the sections 75 and 76.

In the unloader 77, the LCD panels onto which the TCPs have been respectively mounted through the temporary and final bonding steps are taken out of the final bonding section 76 and then, transferred to the stage for the next fabrication process of the LCD device.

FIG. 14 shows an example of the structure of the TCP feeder 78 of the TCP mounting apparatus 70 shown in FIG. 13.

As seen from FIG. 14, the current carrier tape 50 is wound around the carrier tape reel 81 in operation and the new carrier tape 60 is wound around the carrier tape reel 82 on standby. The carrier tape reel 81 is located in an upper level than the carrier tape reel 82. The current carrier tape 50 pulled out from the reel 81 is guided by the rollers 83 to an underlying collecting box 85. Near the start position of the moving path of the current carrier tape 50, the upper and lower base members 10 and 20 are provided. Between the upper and lower base members 10 and 20 and the collecting box 85, a metal die 84 is provided for punching the TCPs out from the tape 50 (or 60). The TCPs thus punched out are collected in the box 85 and thereafter, fed to the temporary bonding section 74 successively.

Since the structure of the TCP mounting apparatus shown in FIGS. 13 and 14 are an example, any other structure may be applied to the present invention.

### Second Embodiment

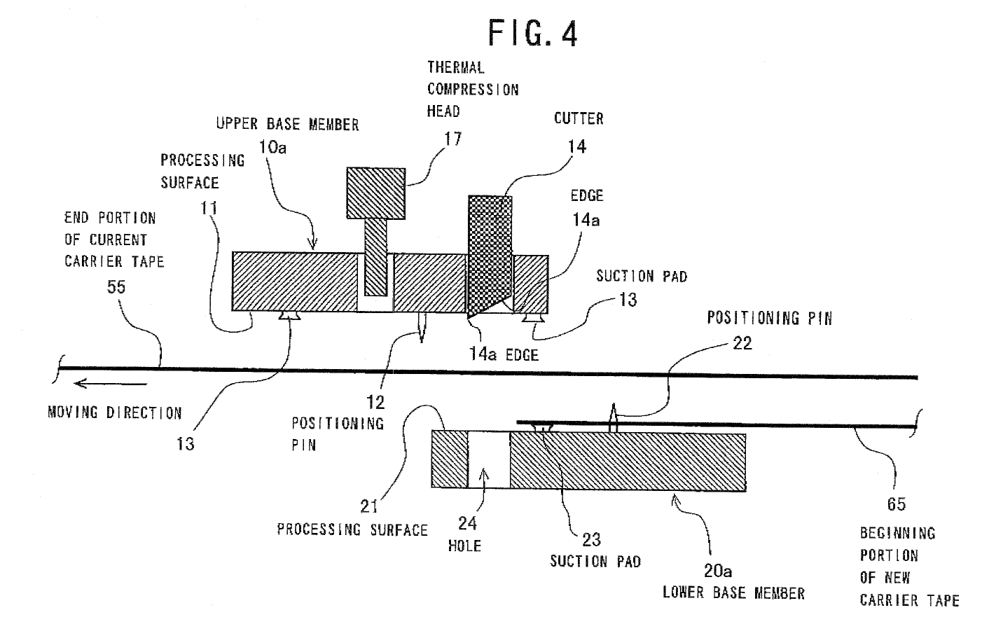

FIG. 4 is a conceptual diagram showing the mechanism (the structure of an apparatus) to be used in the method of connecting carrier tapes in a TCP mounting apparatus according to the second embodiment of the invention. In this method, an upper base member 10a and a lower base member 20a each having the structures shown in FIG. 4 are used. The upper base member 10a and the lower base member 20a of this embodiment correspond to the first movable member and the second movable member in the claims, respectively.

The upper base member 10a, which is located above the moving path of the current carrier tape 50, is movable in the upward and downward directions, similar to the upper base member 10 in the first embodiment. The member 10a comprises a cutter 14 that is the same as the first embodiment; however, it does not comprise a staple supplier 15. A positioning pin 12 and two suction pads 13, which are the same as those of the first embodiment, are formed on the processing surface 11 of the upper base member 10a.

The upper base member 10a further comprises a thermal compression head 17 which is movable upward and downward. The bottom end of the head 17 can be protruded downward from the processing surface 11. The head 17 applies heat locally to the carrier tapes to melt them temporarily at the bottom end thereof, thereby adhering these tapes to each other. Since the structure of the thermal compression head 17 is well known, detailed explanation about it is omitted here.

The lower base member 20a, which is located below the moving path of the current carrier tape 50, is movable in the forward, backward, upward, and downward directions, similar to the lower base member 20 in the first embodiment. The member 20a comprises a penetrating hole 24 that is the same as the first embodiment: however, it does not comprise a staple supplier 25. A positioning pin 22 and a suction pad 23, which are the same as those of the first embodiment, are formed on the processing surface 21 of the lower base member 20a.

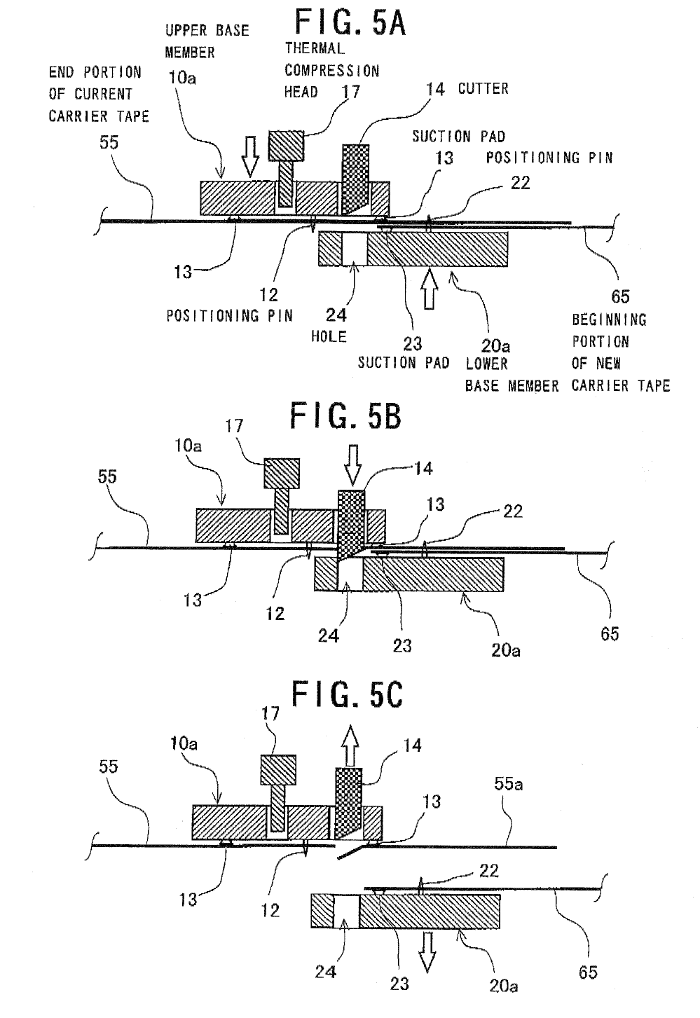

Next, the method of connecting the carrier tapes according to the second embodiment of the invention is explained below with reference to FIG. 4, FIGS. 5A to 5C, FIGS. 6A to 6C, and FIG. 7.

First, as shown in FIG. 4, in the standby state of the lower base member 20a where the member 20a is apart from the moving path of the current carrier tape 50 downward, the beginning portion 65 of the new carrier tape 60 is placed and held on the processing surface 21 of the lower base member 20a. At this time, the positioning pin 22 of the member 20a is inserted into an appropriate one of the sprocket holes 63 of the beginning portion 65 and engaged therewith, thereby conducting the positioning operation of the new carrier tape 60. Moreover, in the vicinity of the top end of the beginning portion 65, the suction pad 23 is sucked onto the lower face (back surface) of the portion 65, thereby holding the new carrier tape 60 on the member 20a in the positioned state. The beginning portion 65 thus positioned and held is located behind the hole 24 and is not overlapped with the same, similar to the first embodiment.

Since the double-sided adhesive tape 30 and other adhesives are not used in the second embodiment, any other operation are unnecessary excluding the positioning and holding operations of the beginning portion 65 of the new carrier tape 60.

When the beginning portion 65 of the new carrier tape 60 is placed on the lower base member 20a, the upper base member 10a is held in its, standby position shown in FIG. 4, where the member 10a is apart from the moving path of the current carrier tape 50 upward.

Next, as shown in FIG. 5A, the upper base member 10a is lowered to the vicinity of the moving path of the current carrier tape 50 and then, the end portion 55 of the current carrier tape 50 is held on the processing surface 11 of the member 10a using the positioning pin 12 and the suction pads 13. At this time, the positioning pin 12 of the member 10a is inserted into an appropriate one of the sprocket holes 53 in the end portion 55 and engaged therewith, thereby conducting the positioning operation of the current carrier tape 50. Moreover, at two appropriate positions in the end portion 55, the suction pads 13 are sucked onto the upper face (surface) of the portion 55, thereby holding the current carrier tape 50 on the member 20a in the positioned state. The end portion 55 thus positioned and held is extended forward and backward with respect to the upper base member 10a. These steps are the same as the first embodiment.

The position at which the end portion 55 of the current carrier tape 50 is held by the upper base member 10a is optionally determined; however, it is preferred that this position is set to be near the body 51 of the current carrier tape 50. This is because it is preferred that the beginning portion 65 of the new carrier tape 60 is connected to the end portion 55 of the current carrier tape 50 at an appropriate position as close to the body 51 of the tape 50 as possible, from the viewpoint of stability after the interconnection.

Subsequently, as shown in FIG. 5A, the lower base member 20a is raised to the vicinity of the moving path of the current carrier tape 50 and then, stopped at a predetermined position that is matched with the position of the upper base member 10a. At this position, the cutter 14 of the upper base member 10a and the hole 24 of the lower base member 20a are superposed to each other. This step is the same as the first embodiment. However, the double-sided adhesive tape 30 is not used here and therefore, the beginning portion 65 of the new carrier tape 60 may be contacted with or apart from the end portion 55 of the current carrier tape 50 at this time.

Next, the cutter 14 on the upper base member 10a is activated to lower the edge 14a. Since the end portion 55 of the current carrier tape 50 is held by the member 10a, the end portion 55 is cut off at an opposing position to the edge 14a and thereafter, the edge 14a goes into the hole 24 through the cutting position of the tape 50, as shown in FIG. 5B. In this way, the end portion 55 of the current carrier tape 50 is cut over its entire width. At this time, since the beginning portion 65 of the new carrier tape 60 does not exist at the position right above the hole 24 of the lower base member 20a, no effect is given to the beginning portion 65. The cutting position of the end portion 55 is automatically determined at the time when the end portion 55 is positioned and held on the upper base member 10a. These steps are the same as the first embodiment.

After the cutting operation of the end portion 55 of the current carrier tape 50 is completed in this way, the cutter 14 is raised and returned to its original position while keeping the upper base member 10a at the same position. On the other hand, the lower base member 20a is lowered to be apart from the moving path of the current carrier tape 50, as shown in FIG. 5C. At this time, the separated part (unnecessary part) 55a of the end portion 55 is being held by the rear suction pad 13 and thus, the part 55a does not fall. This means that the cutting operation of the end portion 55 will not cause any problem in the mounting and moving operations. The state of the beginning portion 65 of the new carrier tape 60 held on the lower base member 20a is the same as that shown in FIG. 4. These steps are the same as the first embodiment.

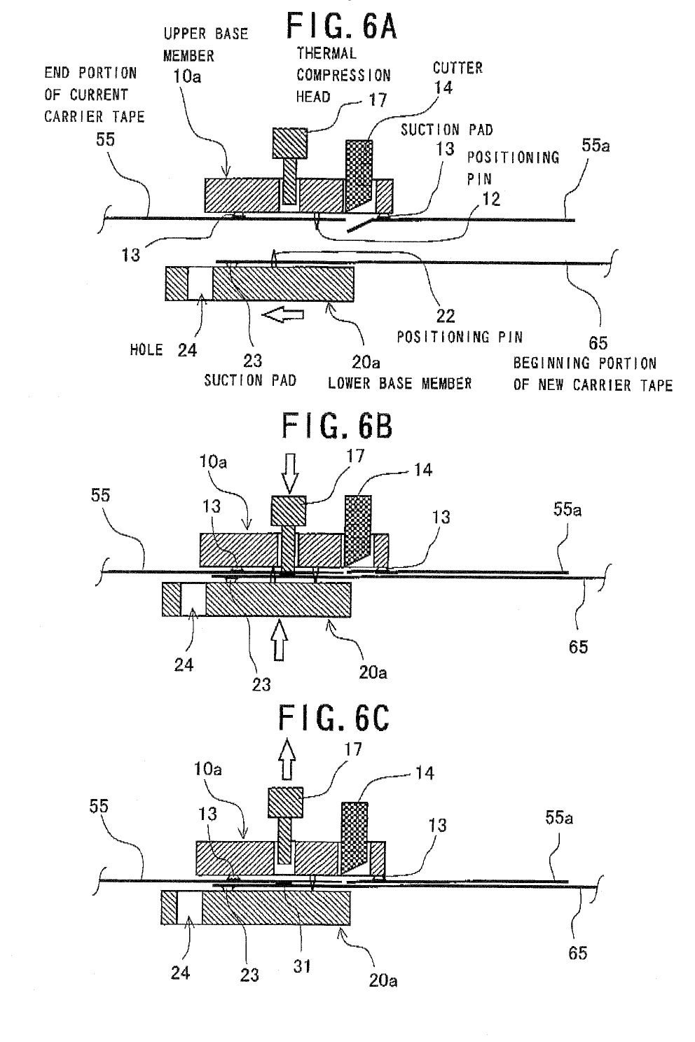

Next, as shown in FIG. 6A, the lower base member 20a is moved forward over a predetermined distance along the moving path of the current carrier tape 50 while keeping the member 20a apart from the said moving path. This is to overlap the beginning portion 65 of the new carrier tape 60 with the remaining end portion 55 of the current carrier tape 50. Since the overlapping position and the overlapping length of the beginning and end portions 65 and 55 are dependent upon the movement distance of the lower base member 20a in this step, the said movement distance may be optionally determined according to the necessity. However, the said movement distance needs to be determined in such a way that the separated or unnecessary part 55a of the end portion 50 (which is kept being held by the upper base member 10a) does not overlap with the lower base member 20a. This step is the same as the first embodiment.

Following this, the lower base member 20a is raised, thereby overlapping the remaining end portion 55 of the current carrier tape 50 and the beginning portion 65 of the new carrier tape 60 and contacting them each other. In this state, since the adhesive tape 30 used in the first embodiment does not exist, the remaining end portion 55 and the beginning portion 65 are directly sandwiched by the processing surface 11 of the upper base member 10a and the processing surface 21 of the lower base member 20a, as shown in FIG. 6B.

Next, while keeping the state of FIG. 6B where the remaining end portion 55 and the beginning portion 65 are sandwiched by the processing surfaces 11 and 21, the thermal compression head 17 on the upper base member 10a is activated, thereby pushing out the bottom end of the head 17 downward from the processing surface 11. Then, the bottom end of the head 17 is contacted with the remaining end portion 55 of the current carrier tape 50 positioned just below the head 17. Since the beginning portion 65 of the new carrier tape 60 is overlapped with the said end portion 55, the heat and pressure generated at the bottom end of the head 17 are locally applied to not only the remaining end portion 55 but also the beginning portion 65. This heating and compression operation is kept for a predetermined time. After the thermal compression is completed in this way, the head 17 is raised to its original position, as shown in FIG. 6C. As a result, due to the locally temporary melting (thermal compression) by heat, the beginning portion 65 of the new carrier tape 60 and the remaining end portion 55 of the current carrier tape 50 are interconnected at the thermal connection section 31. Subsequently, the members 10a and 20a and the tapes 50 and 60 in the state of FIG. 6C are kept in the atmospheric air for a predetermined time, thereby cooling the interconnection section of the portions 55 and 65.

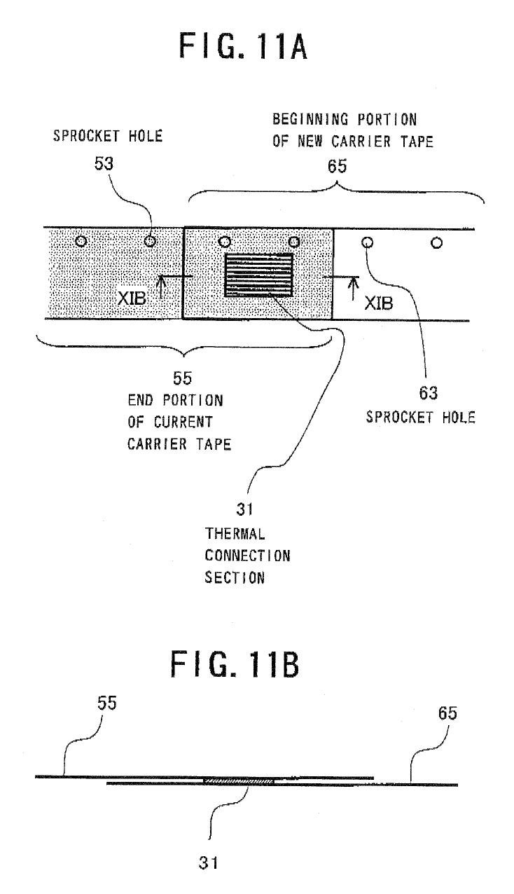

The schematic structure of the thermal connection section 31 of the end portion 55 and the beginning portion 65 is shown in FIGS. 11A and 11B. FIG. 11A is an enlarged schematic plan view of the thermal connection section 31 and FIG. 11B is a partial cross-sectional view along the line XIB-XIB in FIG. 11A.

As shown in FIGS. 11A and 11B, the remaining end portion 55 of the current carrier tape 50 and the beginning portion 65 of the new carrier tape 60 are locally melted and united with each other at the thermal connection section 31. Accordingly, the interconnection strength of the end portion 55 and the beginning portion 65 is surely enhanced compared with the conventional method using staples only. In addition, the interconnection state of the end portion 55 and the beginning portion 65 is stabilized because positional deviation is unlikely to occur between the end and beginning portions 55 and 65.

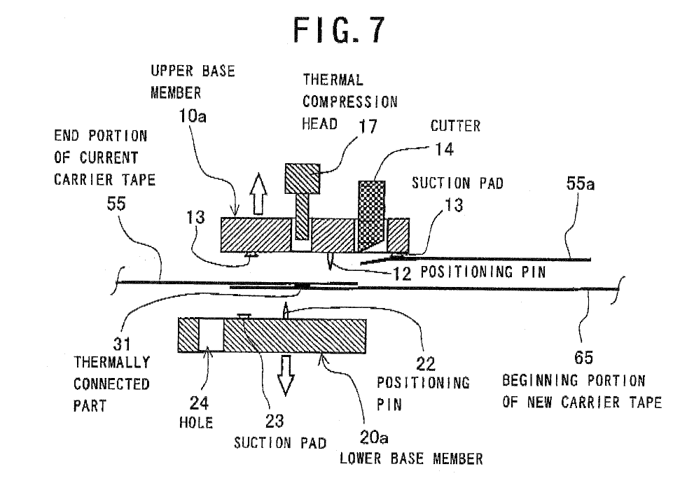

When the thermal compression and cooling step is completed in this way, the interconnection operation of the remaining end portion 55 of the current carrier tape 50 and the beginning portion 65 of the new carrier tape 60 is completed. Then, as shown in FIG. 7, the upper base member 10a is raised and the lower base member 20a is lowered thereby detaching respectively the members 10a and 20a from the end portion 55 and the beginning portion 65 which have been interconnected. Thus, the method of connecting the carrier tapes according to the second embodiment of the invention is completed.

The separated or unnecessary part 55a of the end portion 55 of the current carrier tape 50 held by the upper base member 10a may be detached from the member 10a in the state of FIG. 7.

With the method of connecting carrier tapes according to the second embodiment of the invention, as explained above, the movable upper base member 10a having the cutter 14, the suction pads 13, and the positioning pin 12 and the movable lower base member 20a having the suction pad 23 and the positioning pin 22 are provided in the TCP mounting apparatus.

Then, first the end portion 55 of the current carrier tape 50 is positioned and held on the upper base member 10a, and the beginning portion 65 of the new carrier tape 60 is positioned and held by the lower base member 20a. Subsequently, the end portion 55 of the current carrier tape 50 is sandwiched by the upper and lower base members 10a and 20a and then, the unnecessary part 55a of the end portion 55 is cut off by the cutter 14 of the upper base member 10a. Furthermore, after the beginning portion 65 of the new carrier tape 60 and the remaining end portion 55 of the current carrier tape 50 are overlapped, the beginning portion 65 and the remaining end portion 55 are adhered to each other with the thermal connection section 31. Therefore, the interconnection between the remaining end portion 55 of the current carrier tape 50 and the beginning portion 65 of the new carrier tape 60 can be formed more surely.

Accordingly, the interconnection state between the end portion 55 of the current carrier tape 50 and the beginning portion 65 of the new carrier tape 60 is stabilized and as a result, the problems caused by the instability of the said interconnection state (e.g. the chip-shaped elements or parts in the form of TCP cannot be fed, or the FPC on which the chip-shaped elements or parts have been mounted cannot be divided) can be avoided.

In addition, because it is sufficient that the upper base member 10a having the cutter 14, the suction pads 13, and the positioning pin 12 and the lower base member 20a having the suction pad 23 and the positioning pin 22 are provided and operated in the above-described manner, the method of the second embodiment can be carried out easily.

Furthermore, it is sufficient for the operator that the end portion 55 of the current currier tape 50 is positioned and held by the upper base member 10a, and the beginning portion 65 of the new currier tape 60 is positioned and held by the lower base member 20a, and thereafter, the end and beginning portions 55 and 65 are adhered to each other by thermal compression. The subsequent operations are carried out automatically. Therefore, the burden for the operator does not increase.

In addition, unlike the above-described first embodiment, no staples are used for interconnection of the end portion 55 and the beginning portion 65 in the second embodiment. Therefore, there is an additional advantage that the structures of the base members 10a and 20a can be simplified compared with the first embodiment.

To enhance the interconnection stability of the remaining end portion 55 and the beginning portion 65 in the second embodiment, at least one staple may be supplied from at least one of the upper base member 10a and the lower base member 20a.

The method of connecting carrier tapes according to the second embodiment also can be applied to the fabrication of the LCD device like the above-described first embodiment, if driving semiconductor chips for LCD devices are used as the semiconductor chips arranged (mounted) on the current and new carrier tapes 50 and 60. In this case, an increase in the fabrication cost of the LCD device can be prevented.

Additionally, needless to say, the method of the second embodiment may be applied to other types of the display de vices than the LCD device if it is fabricated using a TCP mounting apparatus.

### Third Embodiment

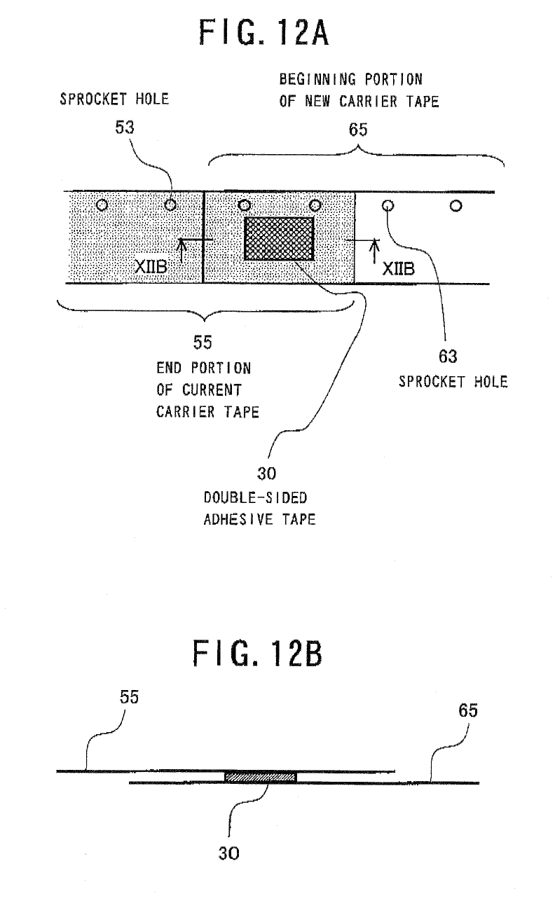

FIG. 12A shows the structure of the interconnection section between the remaining end portion 55 of the current carrier tape 50 and the beginning portion 65 of the new carrier tape 60, which are interconnected by the method of connecting carrier tapes according to the third embodiment of the invention. FIG. 128 shows the cross-section along the line XIIB-XIIB in FIG. 12A.

The method of the third embodiment is the same as the above-described first embodiment except that the staples 16 and 26 are not used and that the interconnection of the end portion 55 of the current carrier tape 50 and the beginning portion 65 of the new carrier tape 60 is accomplished with the double-sided adhesive tape 30 only.

If the adhesion strength of the adhesive tape 30 (or an adhesive) is enough, the use of staples 16 and 26 can be omitted as shown in the third embodiment. Therefore, the method of the third embodiment is more advantageous than that of the first embodiment because the structures of the upper base member 10 and the lower base member 20 can be simplified.

The method of connecting carrier tapes according to the third embodiment also can be applied to the fabrication of the LCD device like the above-described first and second embodiments, if driving semiconductor chips for LCD devices are used as the semiconductor chips arranged (mounted) on the current and new carrier tapes 50 and 60.

The method of the third embodiment may be applied to other types of the display devices than the LCD device if it is fabricated using a TCP mounting apparatus like the above-described first and second embodiments.

### Other Embodiments

The above-described first to third embodiments are concrete examples of the present invention. Therefore, needless to say, the present invention is not limited to these embodiments and any modification is applicable to them.

For example, although staples and a double-sided adhesive tape are used in combination in the first embodiment, thermal compression is used in the second embodiment, and a double-sided adhesive tape is used in the third embodiment, the invention is not limited to these. Any quick-drying or pressure-sensitive adhesive may be coated on the area to which a double-sided adhesive tape should be placed if it provides an interconnection of the end portion of the current carrier tape and the beginning portion of the new carrier tape with desired strength and desired stability.

Moreover, although the upper base member and the lower base member are constituted separately in the above-described embodiments, the invention is not limited to this. A movable member corresponding to the upper base member and another movable member corresponding to the lower base member may be constituted or incorporated in a single member or unit.

Furthermore, the cutting means of the upper base member is not limited to the cutter as used in the above-described embodiments. Any other form of cutter may be used for the present invention if it can out a carrier tape. For example, the cutter may have upper and lower edges and at least one of the upper and lower edges may be moved to cut the unnecessary part of the end portion of the current carrier tape.

The holding means of the upper and lower base members are not limited to the suction pad as used in the above-described embodiments. Any other form of holding mechanism or device may be used for the present invention if it can hold a carrier tape on the upper or lower base member. For example, the holding mechanism or device may include a hook, clip, latch, or catch designed to hold or nip a carrier tape.

The positioning means of the upper and lower base members are not limited to the positioning pin as used in the above-described embodiments. Any other form of positioning mechanism or device may be used for the present invention if it can fix a carrier tape at a desired position on the upper or lower base member. For example, the positioning mechanism or device may be a hook, clip or latch designed to engage with a sprocket hole or holes of a carrier tape.

While the preferred forms of the present invention have been described, it is to be understood that modifications will be apparent to those skilled in the art without departing from the spirit of the invention. The scope of the present invention, therefore, is to be determined solely by the following claims.

What is claimed is:

1. A method of connecting carrier tapes in a TCP mounting apparatus for connecting an end portion of a first carrier tape to a beginning portion of a second carrier tape;
the method comprising the steps of:
providing a first movable member having cutting means, holding means, and positioning means, and a second movable member having holding means and positioning means:
positioning and holding the end portion of the first carrier tape by the first movable member using the positioning means and the holding means of the first movable member;
positioning and holding the beginning portion of the second carrier tape by the second movable member using the positioning means and the holding means of the second movable member;
cutting an unnecessary part of the end portion of the first carrier tape by using the cutting means of the first movable member;
moving the first movable member and/or the second movable member to form an overlapping region where the beginning portion of the second carrier tape and the remaining end portion of the first carrier tape are overlapped, after cutting the unnecessary part of the end portion;
adhering the beginning portion of the second carrier tape and the remaining end portion of the first carrier tape to each other in the overlapping region by bringing the first movable member and the second movable member close to each other; and
detaching respectively the second movable member and the first movable member from the beginning portion of the second carrier tape and the remaining end portion of the first carrier tape, after adhering the beginning portion and the remaining end portion to each other.

2. The method according to claim 1, wherein a double-sided adhesive tape is placed between the beginning portion of the second carrier tape and the remaining end portion of the first carrier tape in the overlapping region in the adhering step of the beginning portion of the second carrier tape and the remaining end portion of the first carrier tape.

3. The method according to claim 1, wherein thermally compressing means is used to form a thermal connection section in the overlapping region in the adhering step of the beginning portion of the second carrier tape and the remaining end portion of the first carrier tape, wherein the beginning portion and the remaining end portion are thermally interconnected in the thermal connection section.

4. The method according to claim 1, wherein staples are additionally applied to the overlapping region in the adhering step of the beginning portion of the second carrier tape and the remaining end portion of the first carrier tape.

5. The method according to claim 1, wherein in the step of cutting the unnecessary part of the end portion of the first carrier tape, the entire beginning portion of the second carrier tape held by the second movable member is located behind a cutting position.

6. The method according to claim 1, wherein after the cutting step of the unnecessary part of the end portion of the first carrier tape is completed, the unnecessary part of the end portion of the first carrier tape is held by the first movable member.

7. The method according to claim 1, wherein the cutting means of the first movable member comprises an edge movable toward the second means, and the second movable member comprises a hole for receiving the edge; and
wherein the edge of the cutting means is moved to enter the hole through the end portion of the first carrier tape in the cutting step of the unnecessary part of the end portion of the first carrier tape.

8. A TCP mounting apparatus comprising:
a first movable member having cutting means, holding means, and positioning means; and
a second movable member having holding means and positioning means;
wherein the end portion of the first carrier tape is positioned and held by the first movable member using the positioning means and the holding means of the first movable member;
the beginning portion of the second carrier tape is positioned and held by the second movable member using the positioning means and the holding means of the second movable member;
an unnecessary part of the end portion of the first carrier tape is cut by using the cutting means of the first movable member;
the first movable member and/or the second movable member is/are moved to form an overlapping region where the beginning portion of the second carrier tape and the remaining end portion of the first carrier tape are overlapped, after cutting the unnecessary part of the end portion;
the beginning portion of the second carrier tape and the remaining end portion of the first carrier tape are adhered to each other in the overlapping region by bringing the first movable member and the second movable member close to each other; and
the second movable member and the first movable member are detached respectively from the beginning portion of the second carrier tape and the remaining end portion of the first carrier tape, after adhering the beginning portion and the remaining and portion to each other.

9. A method of fabricating a display device, wherein a first movable member having cutting means, holding means, and positioning means, and a second movable member having holding means and positioning means are provided, and semiconductor chips are arranged on a first carrier tape and a second carrier tape, respectively;
the method comprising the steps of:
after all the semiconductor chips arranged on the first carrier tape are mounted on respective external devices;
positioning and holding an end portion of the first carrier tape by the first movable member using the positioning means and the holding means of the first movable member;
positioning and holding a beginning portion of the second carrier tape by the second movable member using the positioning means and the holding means of the second movable member;
cutting an unnecessary part of the end portion of the first carrier tape by using the cutting means of the first movable member;
moving the first movable member and/or the second movable member to form an overlapping region where the beginning portion of the second carrier tape and the remaining end portion of the first carrier tape are overlapped, after cutting the unnecessary part of the end portion;
adhering the beginning portion of the second carrier tape and the remaining end portion of the first carrier tape to each other in the overlapping region by bringing the first movable member and the second movable member close to each other,
detaching respectively the second movable member and the first movable member from the beginning portion of the second carrier tape and the remaining end portion of the first carrier tape, after adhering the beginning portion and the remaining end portion to each other; and
mounting the semiconductor chips arranged on the second carrier tape on respective external devices, successively.
